(19) United States
(12) Patent Application Publication
(10) Pub. No.: US 2018/0040587 A1
(43) Pub. Date: Feb. 8, 2018

(54) Vertical Memory Module Enabled by Fan-Out Redistribution Layer

(71) Applicant: Invensas Corporation, San Jose, CA (US)

(72) Inventors: Min Tao, San Jose, CA (US); Zhuowen Sun, Campbell, CA (US); Belgacem Haba, Saratoga, CA (US); Hoki Kim, Santa Clara, CA (US); Wael Zohni, Campbell, CA (US); Shaowu Huang, Sunnyvale, CA (US)

(73) Assignee: Invensas Corporation, San Jose, CA (US)

(21) Appl. No.: 15/669,269

(22) Filed: Aug. 4, 2017

Related U.S. Application Data
(60) Provisional application No. 62/372,208, filed on Aug. 8, 2016.

(51) Int. Cl. H01L 25/065; H01L 23/367; H01L 25/18; H01L 23/31; H01L 25/00; H01L 23/00

(52) U.S. Cl. CPC H01L 25/0655; H01L 25/50; H01L 24/82; H01L 24/05; H01L 25/18; H01L 23/3128; H01L 24/32; H01L 23/3675; H01L 24/24; H01L 24/73; H01L 24/92; H01L 2924/1436; H01L 2924/1431; H01L 2224/211; H01L 2224/24137; H01L 2224/32137; H01L 2224/0401; H01L 2224/92144; H01L 24/83; H01L 2224/73217

(57) ABSTRACT

Vertical memory modules enabled by fan-out redistribution layer(s) (RDLs) are provided. Memory dies may be stacked with each die having a signal pad directed to a sidewall of the die. A redistribution layer (RDL) is built on sidewalls of the stacked dies and coupled with the signal pads. The RDL may fan-out to UBM and solder balls, for example. An alternative process reconstitutes dies on a carrier with a first RDL on a front side of the dies. The dies and first RDL are encapsulated, and the modules vertically disposed for a second reconstitution on a second carrier. A second RDL is applied to exposed contacts of the vertically disposed modules and first RDLs. The vertical modules and second RDL are encapsulated in turn with a second mold material. The assembly may be singulated into individual memory modules, each with a fan-out RDL on the sidewalls of the vertically disposed dies.

### RELATED APPLICATIONS

This patent application claims the benefit of priority to U.S. Provisional Patent Application No. 62/372,208 to Tao et al, filed Aug. 8, 2016, entitled, “Vertical Memory Module Enabled By Fan-Out Redistribution Layer,” incorporated by reference herein in its entirety.

### BACKGROUND

Ongoing improvements in high-speed, high-bandwidth, and high-capacity memory modules drive a need for improved packaging solutions. The computer memory industry seeks novel packaging solutions for double data rate fifth-generation synchronous dynamic random-access memory (DDR5), for example. Wirebond-based dual-die packaging (DDP) solutions have not been suitable for supporting random access memory speeds of 2933/3200 MHz needed for DDR5. Alternative solutions, such as through-silicon-via (TSV)-based solutions, such as 4H TSV packaging, are very expensive and not in high volume production.

Desirable features for improved packaging include multi-die stacking, in which connections between any two given points can be made shorter to provide lower parasitic resistance and capacitance values compared to traditional packaging approaches. Moreover, desirable packaging technology should have a relatively low cost for mass production.

A natural progression suggests that flip chip technology—controlled collapse chip connection (C4), and wafer-level packaging technologies may be the next platforms for DRAM packaging. These solutions have the possible bottleneck of not being able to stack dies in a package without using TSVs or some through-mold interconnects. Side-by-side packaging, by contrast, also has the bottleneck of increasing the side dimension of the package and has limited application in DIMM production.

### SUMMARY

This disclosure describes vertical memory modules, such as dual inline memory modules (DIMMs), enabled by fan-out redistribution layers. Memory dies may be stacked with each memory die having a signal pad directed to a sidewall at one end of the die. A redistribution layer (RDL) is built on sidewalls of the stacked dies and coupled with the signal pads at the sidewalls. The RDL may fan-out to UBM and solder balls, for example. An alternative process reconstitutes dies on a carrier with a first RDL on a front side of the dies. The dies and first RDL are encapsulated, and the modules vertically disposed for a second reconstitution on a second carrier. A second RDL is applied to exposed contacts of the vertically disposed modules and first RDLs. The vertical modules and second RDL are encapsulated in turn with a second mold material. The assembly may be singulated into individual memory modules, each with a fan-out RDL on the sidewalls of the vertically disposed dies.

### BRIEF DESCRIPTION OF THE DRAWINGS

FIG. 1 is a diagram of an example memory module configuration, with vertical memory dies and a redistribution layer (RDL) applied on sidewall edges of the vertical memory dies.

FIG. 2 is a diagram of an example wafer-level construction technique of routing signal pads to a sidewall at one end of each memory die.

FIG. 3 is a diagram of an example construction technique of stacking memory dies.

FIG. 4 is a diagram of an example construction technique of mounting memory die modules on a carrier wafer with adhesive.

FIG. 5 is a diagram of an example construction technique of revealing signal pads on sidewalls of vertically mounted memory dies.

FIG. 6 is a diagram of example RDLs applied to exposed signal pads on sidewalls of the vertically mounted memory dies.

FIG. 7 is a diagram of an example construction technique of singulating individual memory modules from the wafer-level process.

FIG. 8 is a diagram of an example construction technique of an alternative process of reconstituting single memory chips into memory modules with fan-out RDL on sidewalls.

FIG. 9 is a diagram of an example construction technique of building a first RDL on front faces of memory chips, with signal pads directed to a side.

FIG. 10 is a diagram of an example construction technique of stacking reconstituted assemblies for making memory modules for vertical mount.

FIG. 11 is a diagram of an example construction technique of vertically mounting memory modules including first RDLs on a second carrier wafer.

FIG. 12 is a diagram of an example construction technique of exposing signal pads of the vertically mounted memory modules for application of a second RDL layer on the sidewalls of the vertically mounted memory modules to make a reconstituted assembly.

FIG. 13 is a diagram of an example construction technique of singulating the reconstituted assembly of FIG. 12 into individual memory modules.

FIG. 14 is a diagram of an example memory module using a ZiBond bonding technique instead of an adhesive, between vertical memory dies.

FIG. 15 is a diagram of an example vertical memory module enabled by fan-out RDL including a logic chip at the end of the vertical stack of dies in the memory module.

FIG. 16 is a diagram of an example vertical memory module enabled by fan-out RDL including a logic chip in the middle of the vertical stack of dies in the memory module.

FIG. 17 is a diagram of an example vertical memory module enabled by fan-out RDL including a logic chip connected to the RDL on an opposing side of the RDL from the signal pads and sidewalls of the vertically mounted memory dies.

FIG. 18 is a diagram of an example die-face-up fan-out configuration with die backside film on a carrier wafer.

FIG. 19 is a diagram of an example vertical memory module enabled by fan-out RDL including RDL on or near both sidewalls of the vertically stacked memory dies for optional stacking on the back side of the package.

FIG. 20 is a diagram of an example vertical memory module enabled by fan-out RDL including embedded passive components.

FIG. 21 is a diagram of an example vertical memory module enabled by fan-out RDL with heat dissipating structures and layers.

FIG. 22 is a diagram of an example vertical memory module enabled by fan-out RDL with tilted memory dies to provide a larger target area for vertical connection between conductive elements of an RDL and tilted signal pads of the stacked memory dies.

FIG. 23 is a flow diagram of an example method of making a memory module enabled by a fan-out redistribution layer (RDL).

FIG. 24 is a flow diagram of an example alternative method of making a memory module enabled by a fan-out redistribution layer (RDL).

FIG. 25 is a flow diagram of an example method of making a memory module enabled by a fan-out redistribution layer (RDL) with tilted memory dies and tilted signal pads.

### DETAILED DESCRIPTION

This disclosure describes vertical memory modules, such as dual inline memory modules (DIMMs), enabled by fan-out redistribution layers (RDLs) on silicon sidewalls. In an implementation, an example module is composed of a fan-out wafer-level package for memory that has one or more RDL layers built on one side of the memory die, or on one side of a stack of memory dies, or on one side of a combination of memory dies and logic dies. In an implementation, the die stack may be tilted to allow easier access to the memory sidewall pads, for RDL patterning.

In example memory modules with RDLs on the silicon sidewalls, the memory dies or logic dies all have their signal pads routed to one side, either on the silicon or on a mold material, with fan-out of conductive lines for building vertical RDLs.

In an implementation, a high density, high bandwidth dynamic random-access memory (DRAM) module, with multiple memory chips vertically stacked (e.g., V-DIMM), has signal lines directed to one side and routed out through one or more sidewall RDL layers, in one implementation without solder joints.

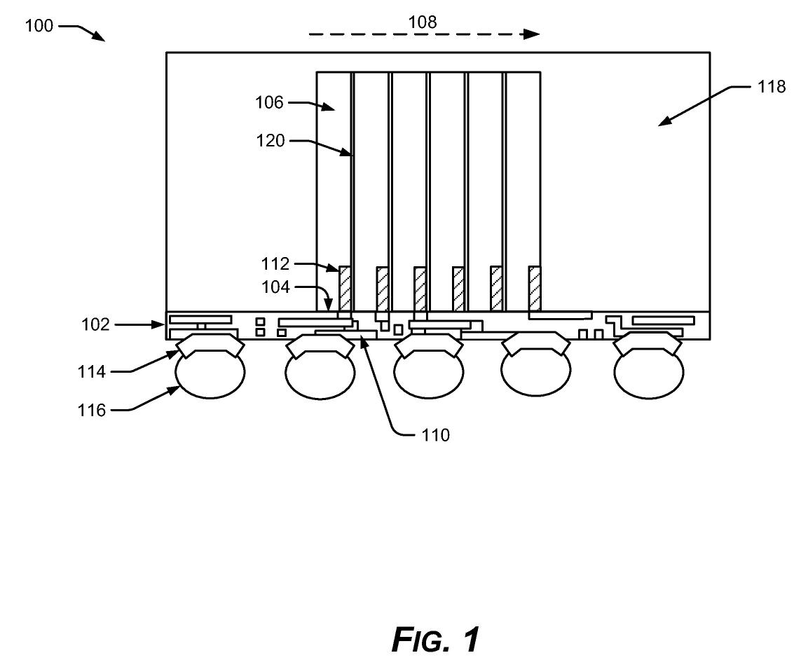

FIG. 1 shows an example memory module 100 with a fan-out redistribution layer (RDL) 102 on sidewalls 104 of the stacked dies 106. An example process disposes the memory chips 106 or “dies” in a vertical stack 108 with a signal pad 112 of each memory chip 106 placed at or near one end of the length of the memory chip 106. The sides of the memory chip 106 at each end can be referred to as the sidewalls 104, or sidewall sides 104, or just “sides” 104 of the memory chip 106. The example process disposes the memory chips 106 in the vertical stack 108 and then builds one or more redistribution layers (RDLs) 102 on the sidewalls 104 (aligned sidewall sides) of the memory chips 106, applying fan-out wafer-level package technology from the signal pads of the memory chips 106. The process may be a die first process, a RDL first process, or a process that implements fan-out RDL construction on individual memory chips first.

The example memory module 100 has the multiple stacked memory dies 106 or a combination of DRAM dies and logic dies stacked vertically 108 with one side 104 of each memory die 106 commonly aligned. Then RDL(s) 102 are provided to, and fanned-out on, that one side 104, with metal lines 110 of the RDL 102 exposed, for example, by mechanical polishing or etching. In an implementation, the exposed metal lines 110 of the RDL 102 may be further developed into under bump metallization (UBM) 114 and solder balls 116. The resulting device contains multiple dies 106 vertically stacked 108 in a fan-out wafer-level package 100, with RDL 102 built on the sidewalls 104. The example device, including the stacked memory dies 106, the RDL 102, and other optional components may be encapsulated with a mold material or other encapsulation 118. The memory dies 106 may also be secured to each other in the vertical stack 108 with an adhesive 120 or other bonding technique. The example memory module 100 can be used as a small form-factor stand-alone vertical DIMM module, or as a high density memory package in a standard DIMM module, or can be used as a stand-alone memory module like a hybrid memory cube (HMC) or high bandwidth memory (HBM).

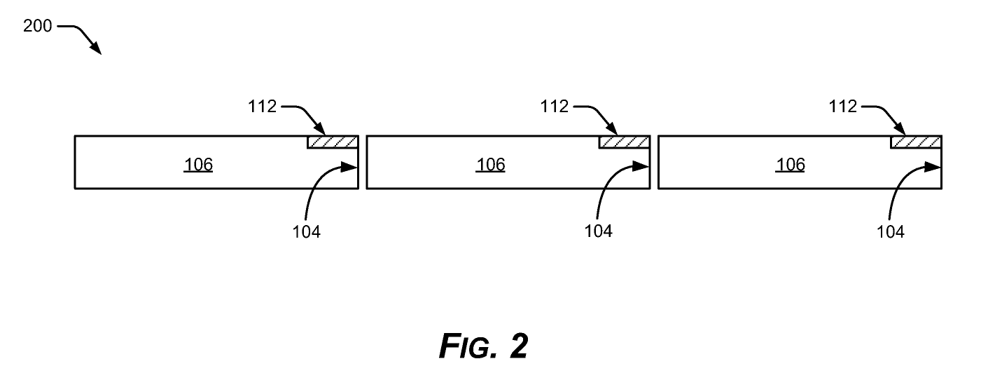

FIG. 2 shows an example previous construction step of making the memory dies 106, including routing the signal pads 112 to one edge or one side 104 of the memory dies 106 in a common direction, at the wafer level. The memory dies 106 may then be singulated to individual chips 106. The dies 106 may be sorted and ranked according to performance from high performance known-good-dies (KGD) to non-functioning dies, which may be discarded or recycled.

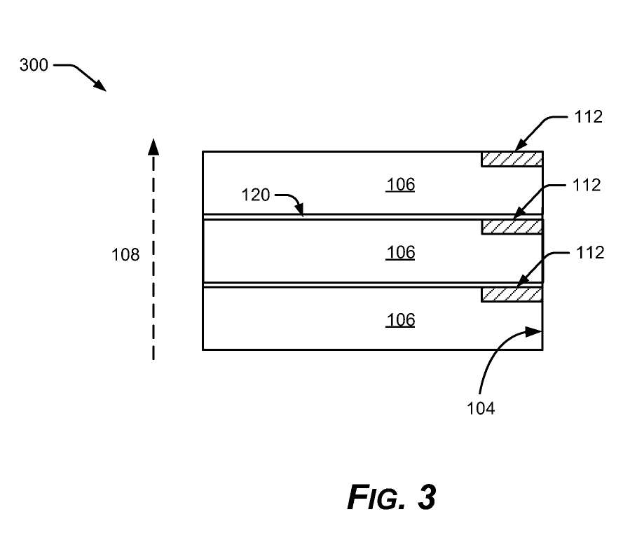

FIG. 3 shows an example construction step of stacking or creating a stack 108 of multiple known-good-dies into a chip module 300, for example with an adhesive 120, and then curing. An example adhesive 120 is ideally nonconductive, capable of withstanding an RDL processing temperature greater than, for example, 250° C., and possesses a consistent thickness. Example adhesives 120 may include silicones, Henkel's® dicing die attach film (DDF), and so forth.

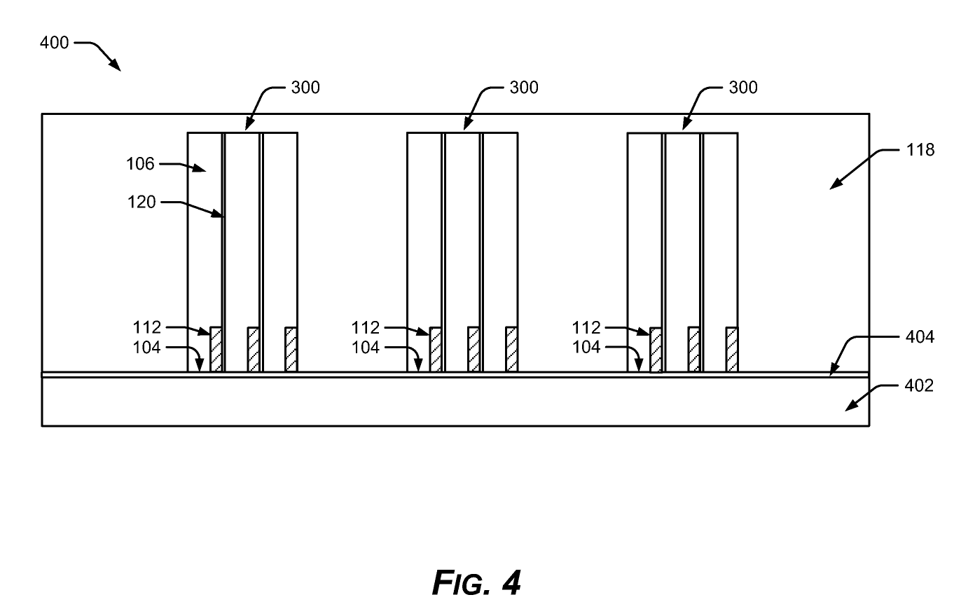

FIG. 4 shows example wafer-level memory modules 400. An example construction technique mounts the chip modules 300 as in FIG. 3 on a carrier wafer 402 secured with an adhesive tape 404, with the signal side 406 facing down (e.g., a reconstitution process). The assembled components may then be overmolded with an encapsulant 118 or a mold material.

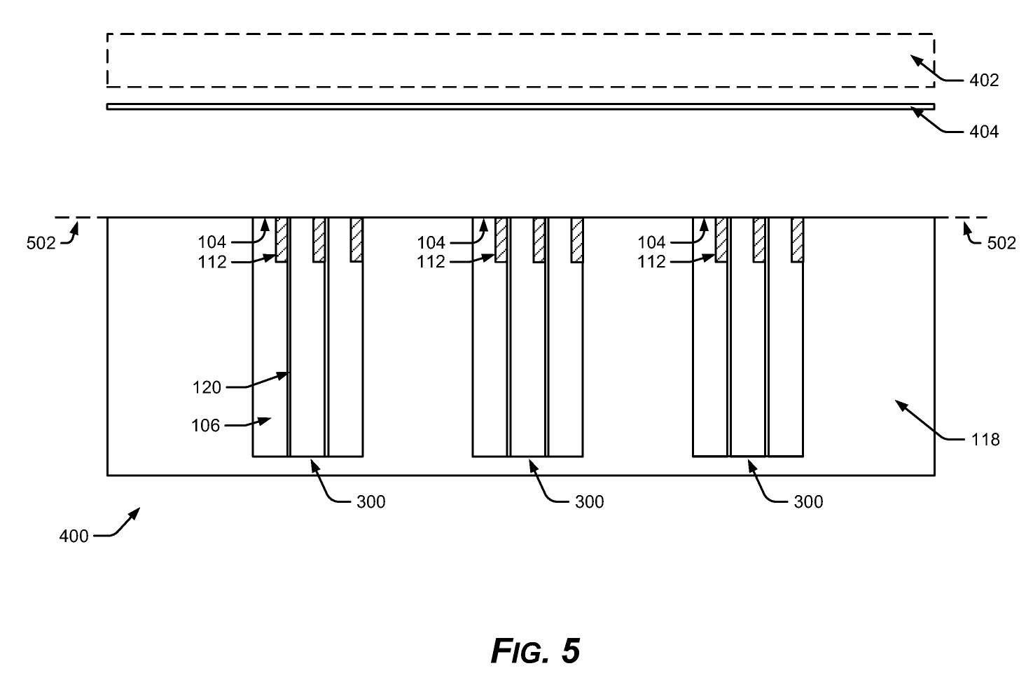

FIG. 5 further shows an example construction technique of peeling off the adhesive tape 404 and releasing the carrier wafer 402 from the wafer-level memory modules 400. The memory modules assembly 400 is then flipped over, and can be ground back 502 or etched 502 to reveal the signal pads 112 on the sidewalls 104.

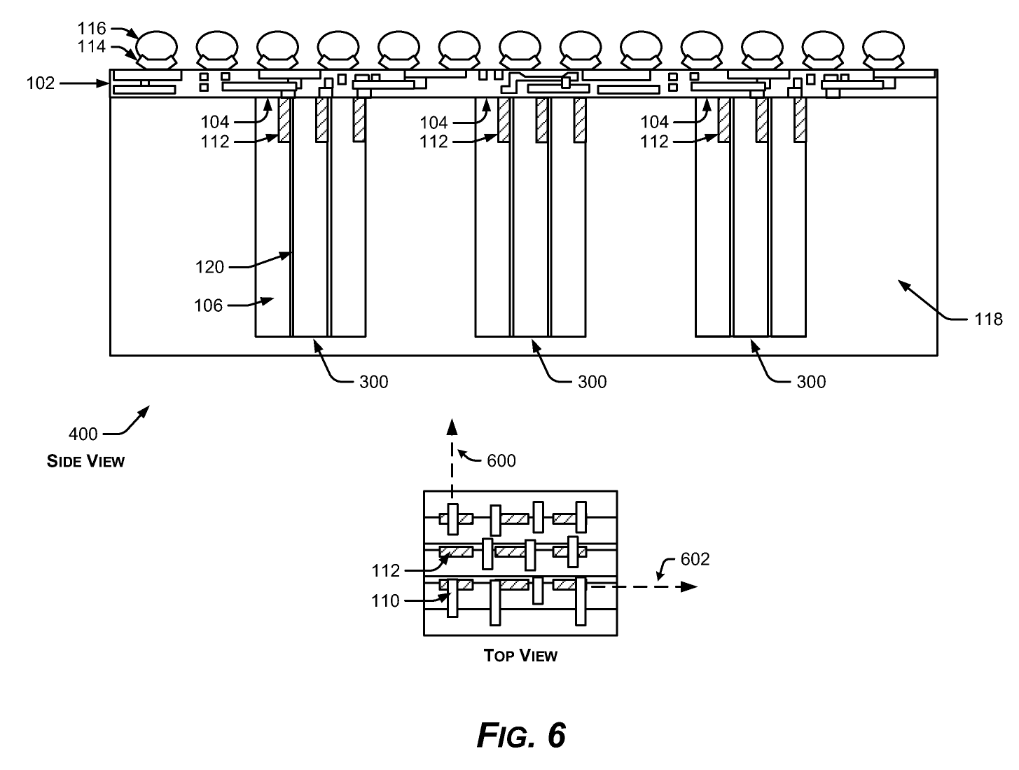

FIG. 6 shows an example construction technique of building one or more redistribution layers (RDLs) 102 on the exposed signal surfaces at the sidewalls 104 of the chip modules 300 in the example wafer-level memory modules 400. Then, in an implementation, the RDL conductors 110 may be plated for under bump metallization (UBM) 114, and solder balls 116 may be attached. In an implementation, the orientation 600 of the conductive lines 110 in the RDLs 102 may be at right angles to the orientation of the signal pads 112 of the memory dies 106.

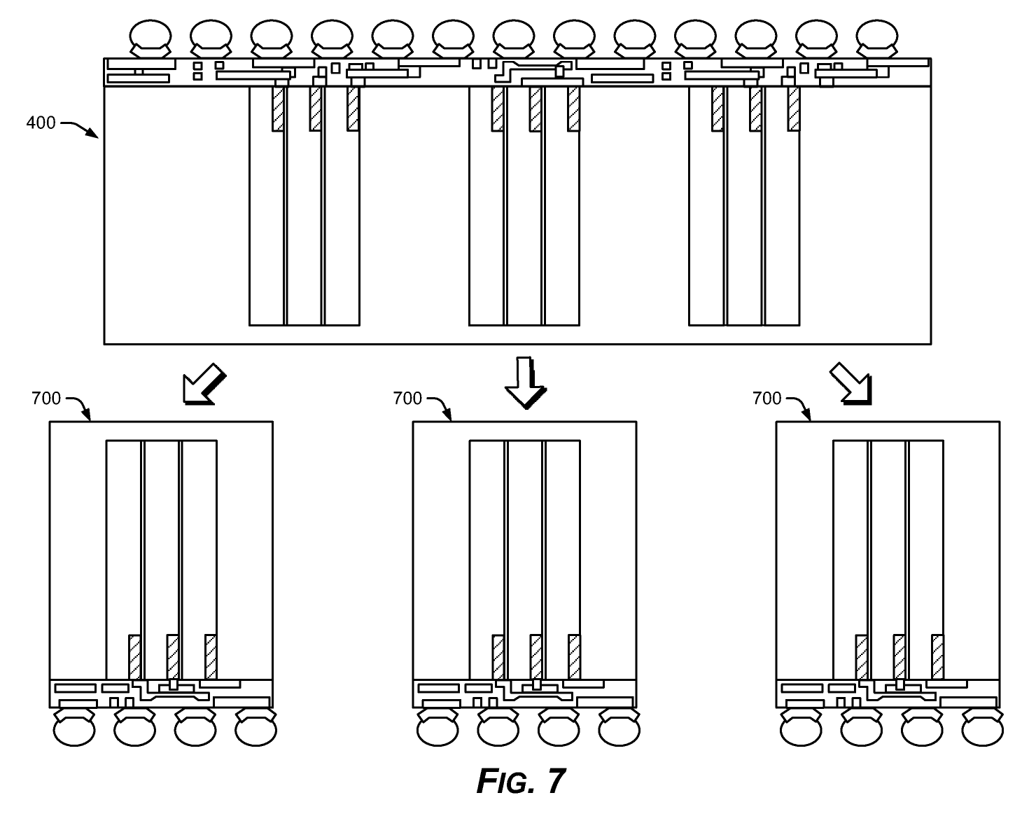

FIG. 7 shows an example construction technique of dicing or otherwise singulating the wafer-level memory modules 400 into individual memory modules 700.

In an implementation, the example construction process of FIGS. 2-7 can be an all wafer-level batch process applying mature eWLB-like (embedded wafer-level ball grid array)-like fan-out technology, for example. Or, in an implementation, the example construction process can be a RDL-first based wafer-level process, with die stack mounted to the RDLs with fine pitch solder joints.

In an implementation, a suitable die attach material is used for stacking that is compatible with the RDL process being used. The sides 104 that have the pads 112 are polished and the pads 112 can be revealed without damaging the active silicon. The sides 104 can be patterned with good alignment, but the alignment requirement is not strict. For example, the x dimension may be within the die thickness, and the y dimension may be within the memory chip input/output pitch.

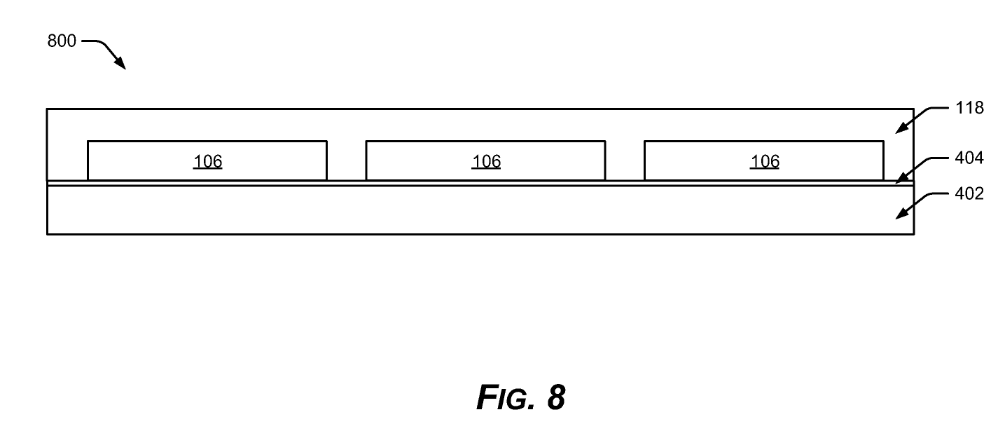

FIGS. 8-13 show stages of an alternative example process for making example memory modules 1300 enabled by redistribution layers (RDLs) 102 & 1200.

In FIG. 8, in a reconstitution process, single known-good-die memory chips 106 are placed horizontally on a first carrier wafer 402 to make an example wafer-level assembly 800. Then the reconstituted assembly 800 is overmolded with an encapsulant 118 or a mold material.

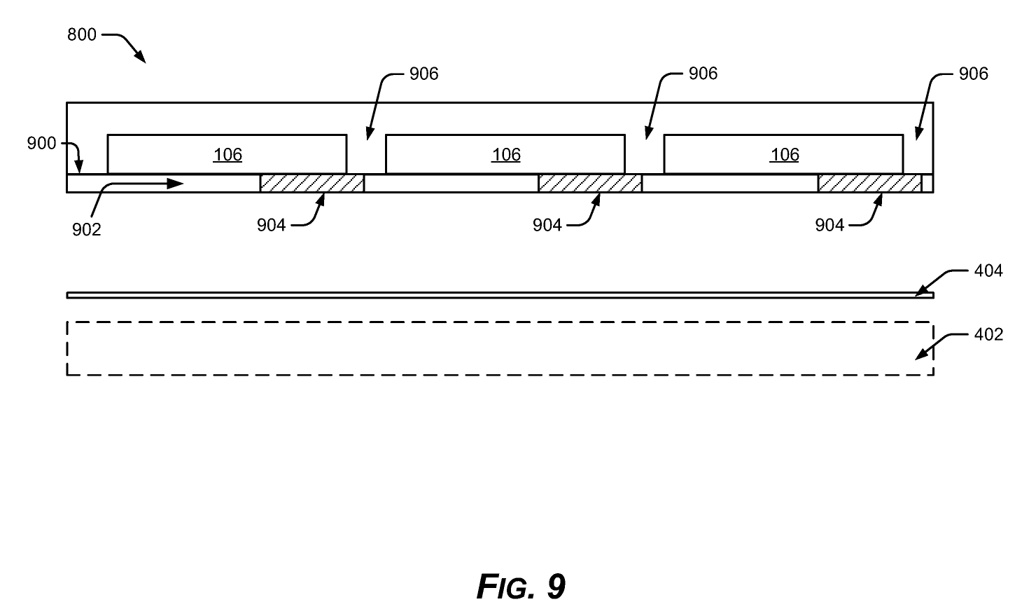

In FIG. 9, the carrier wafer 402 is removed from the example wafer-level assembly 800, and a first, thick, redistribution layer (RDL) 902 is built on the front side 900 of the chips 106, with the RDL signal pads 904 that are associated with each chip 106 routed in the same direction, toward the molding material region 906 that is between the chips 106.

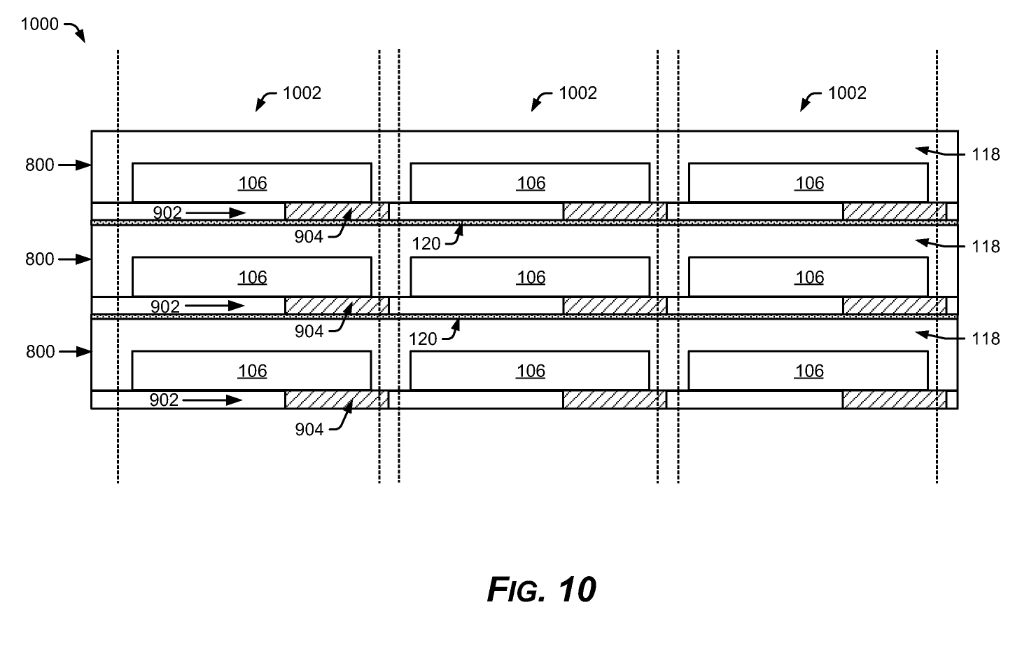

In FIG. 10, multiple instances the reconstituted chip assemblies 800 are disposed into a stack 1000 with intervening adhesive layers 120. The example stack 1000 is then diced into local stacks 1002 of memory chips 106 so that the dicing cuts reveal the thick RDL pads 904 in the mold. In an implementation, passivation components may also be optionally embedded, for example, in the molding material 118 or in the respective adhesive layers 120 attached to the RDL pads 904, or else a discrete passivation layer (not shown) may also be included.

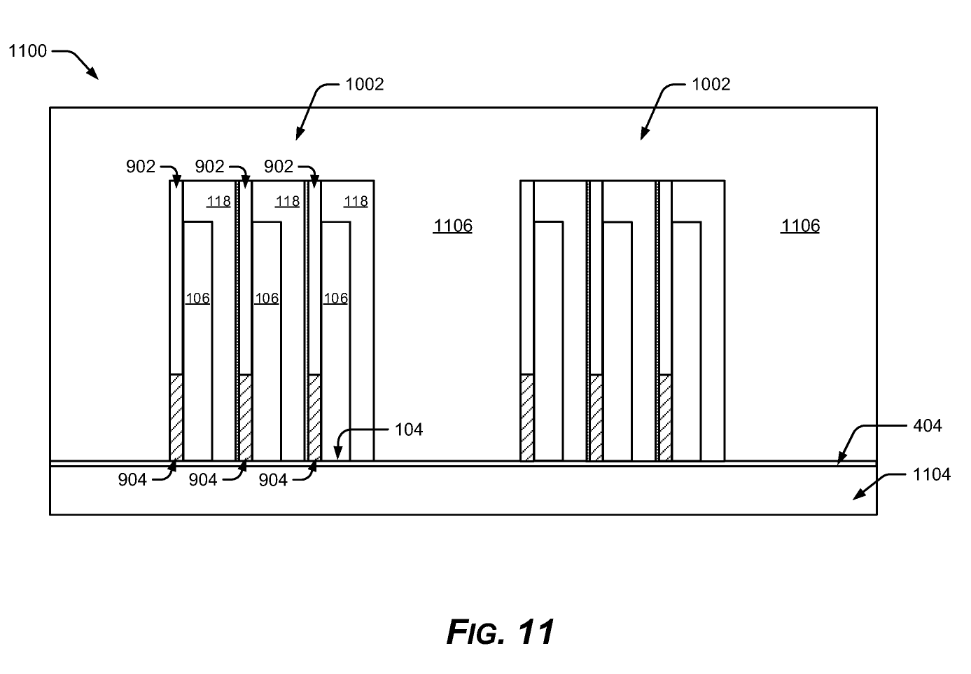

In FIG. 11, the local stacks 1002 of memory chips 106 are vertically reconstituted on a second carrier wafer 1104 into an assembly 1100, with the exposed side 900 that possesses the revealed thick RDL pads 904 oriented down. This vertically reconstituted assembly 1100 is now overmolded again with a second molding material 1006 or other encapsulation.

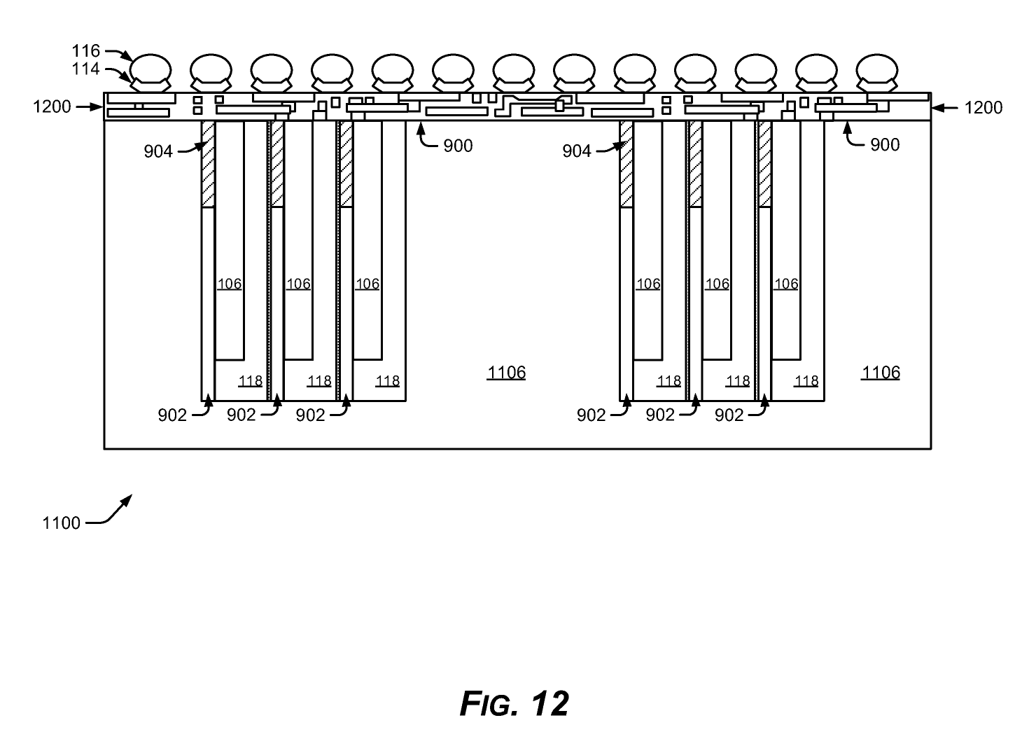

In FIG. 12, the second carrier wafer 1104 is removed. In a second RDL process, one or more layers of RDL 1200 are built on the exposed sides 900 of the RDL pads 904. Under bump metallization (UBM) 114 may then be created on the second RDL(s) 1200. Solder balls 116 may be formed on the UBM layer 114.

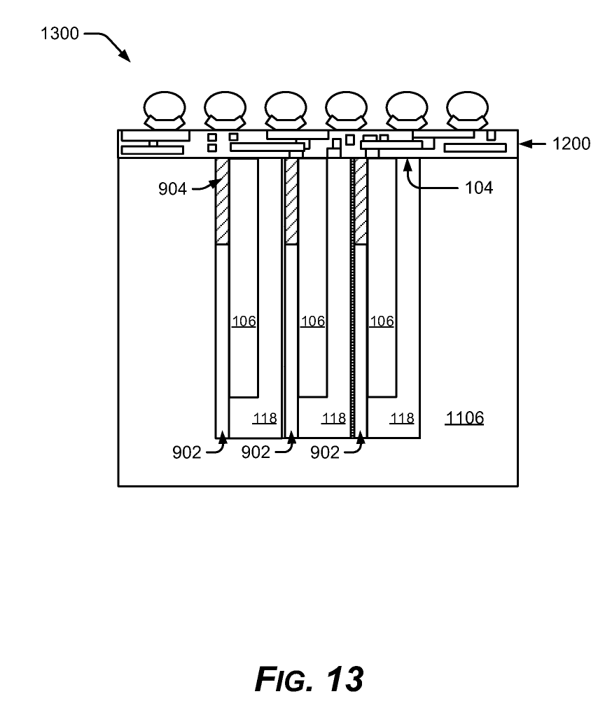

In FIG. 13, the overall wafer-level assembly 1100 may be singulated into individual memory modules 1300, each with a group of stacked memory chips 106 and the fan-out RDL(s) 1200.

This alternative construction process of FIGS. 8-13 utilizes multiple RDL building stages 902 & 1200 and multiple steps of molding or encapsulation 118 & 1106. The memory chips 106 are stacked 1000 at the wafer level, routing pads 904 are extended to the local mold region 906, and the process can provide higher yield and improved reliability for the vertical (first) RDL 902, over conventional processes. This alternative approach is capable of enabling a RDL-first process in the vertical fan-out, with the RDL 902 & 1200 either on conventional silicon or glass.

The example vertical memory modules 1300 with fan-out redistribution layers (RDLs) 1200 on silicon sidewalls 104 and associated production methods described above provide various improvements over conventional vertical memory packages. There is a clear electrical performance benefit because all of the signals go to one common side 900 and directly connect to RDLs 902 & 1200 without long wires and significantly, without solder balls being utilized within the interior of the package.

The example vertical memory modules 1300 with fan-out redistribution layers (RDLs) 1200 on silicon sidewalls 104 also result in a low parasitic resistance, and enable short, and near equal stub length for up to all of the dies 106 and pins. The example vertical memory packages 1300 can also enable high density, high bandwidth memory packaging without input/output budget constraint using fan-out processes, as long as the z-height is not a constraint, for example.

In this alternative process flow of FIGS. 8-13 with the vertical (first) RDL 902 embedded in the second overmold 1106, damaging the active silicon is also minimized or removed as a concern. The example memory modules 1300 produced can be used as memory for DIMM-in-a-package, can be used as solder-down solutions, and can be used as individual memory modules for high-bandwidth applications (for example, as replacements using clamping sockets). The construction processes for the example memory modules 1300 with fan-out redistribution layers (RDLs) 1200 on silicon sidewalls 104 or other sidewalls 104 can have a low manufacturing cost and favorable mass production compatibility, and can utilize mature fan-out wafer-level processing technologies and mature die stacking technologies with good yield.

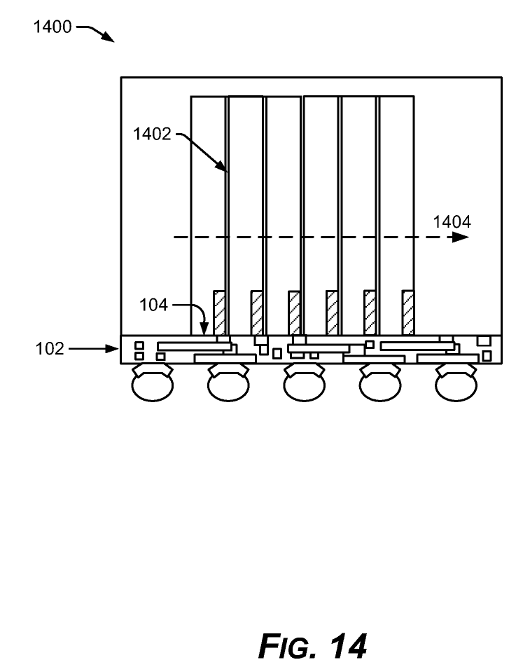

FIG. 14 shows an additional embodiment of the example vertical memory modules 1400 with fan-out redistribution layers (RDLs) 102 on silicon sidewalls 104. In this embodiment, ZiBond® (as shown) or Direct Bond Interconnect (DBI®) bonding techniques 1402 may be used for the vertical die stacking 1404, instead of an adhesive 404 (Invensas Corporation, San Jose, Calif.). These bonding techniques provide a low-temperature bond that enables room temperature die or wafer-level 3D integration without a need for the application of external pressure. DBI is a low-temperature, hybrid bonding technology that integrates electrical interconnects, offering some of the finest pitches available and a lowest cost-of-ownership 3D interconnect platform. Both ZiBond and DBI deliver the fastest bonding throughput currently available in the industry, resulting in up to a 15× increase in wafer bonding throughput. Additionally, low processing temperatures significantly reduce equipment and process cost for high volume manufacturing.

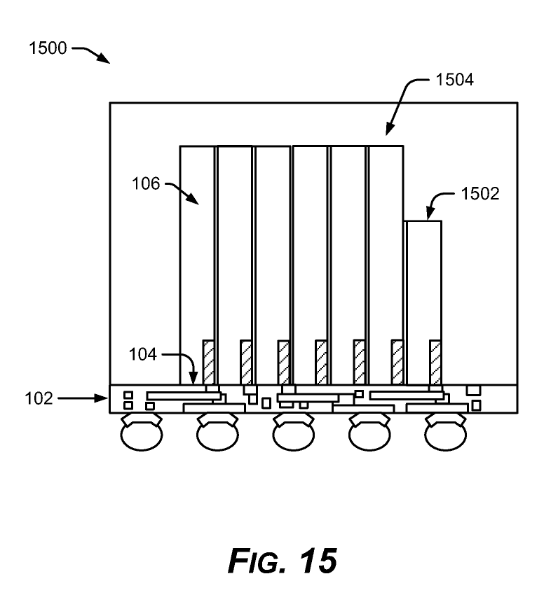

FIG. 15 shows another additional embodiment of the example vertical memory modules 1500 with fan-out redistribution layers (RDLs) 102 on silicon sidewalls 104 or other sidewalls 104. A logic chip 1502 may be added to the end of the memory chip stack 1504 and packed together in the fan-out package 1500. The logic chip 1502 may be a buffer, a controller, an equalizer, and so forth, for performance improvement of added function. The various dies 106 in the stack 1504, including logic dies 1502 or memory die 106, may be electrically coupled together through DBI connections, through the RDL layer 102, or through both.

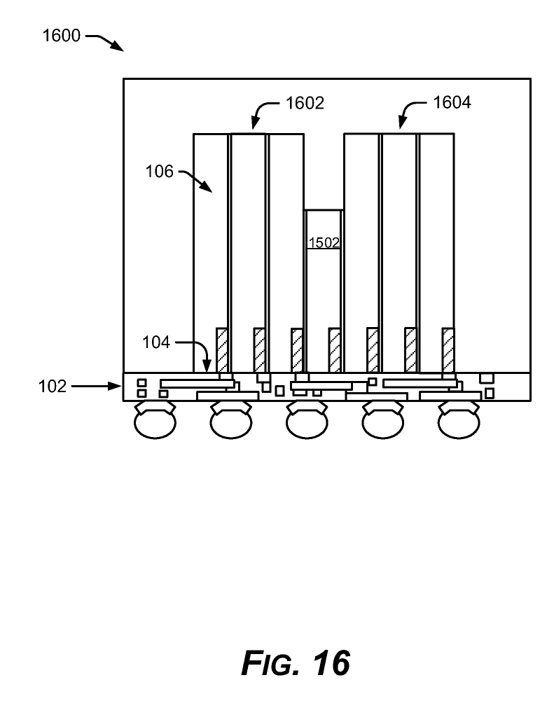

FIG. 16. shows another additional embodiment of the example vertical memory modules 1600 with fan-out redistribution layers (RDLs) 102 on silicon sidewalls 104 or other sidewalls 104. A logic chip 1502 may be added within the middle of the memory chip stack(s) 1602 & 1604 and packed together in the fan-out package 1600. The logic chip 1502 may be a buffer, a controller, an equalizer, a redriver, and so forth, for performance improvement or added function.

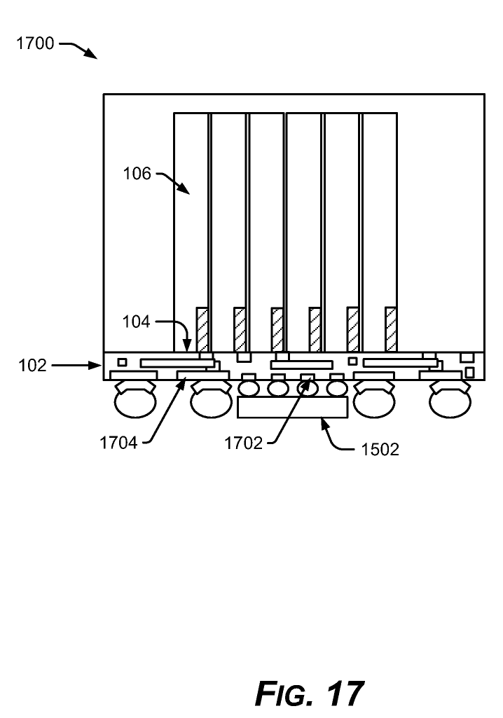

FIG. 17 shows another additional embodiment of the example vertical memory modules 1700 with fan-out redistribution layers (RDLs) 102 on silicon sidewalls 104 or other sidewalls 104. Smaller conductive pads 1702 are plated on the backside of the wafer-level package 1700, as well as larger pads 1704 for fan-out to attach a ball grid array (BGA) 1706. A logic chip 1502 is attached to the smaller pads 1702. The logic chip 1502 may be a buffer, a controller, an equalizer, redriver, and so forth, for performance improvement, or added function.

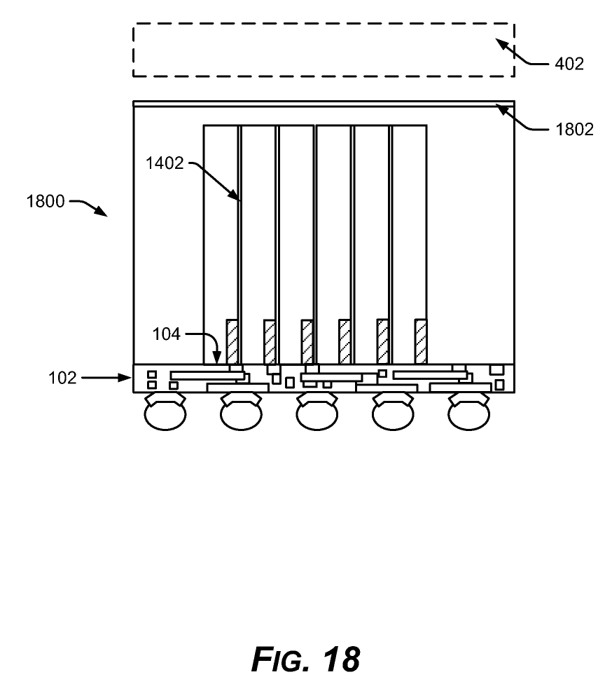

FIG. 18 shows another additional embodiment of the example vertical memory modules 1800 with fan-out redistribution layers (RDLs) 102 on silicon sidewalls 104 or other sidewalls 104. A die backside film 1802, on a carrier wafer 402, for example, may be used in a DECA-like process, in a die face-up fan-out configuration (Deca Technologies, Tempe Ariz.).

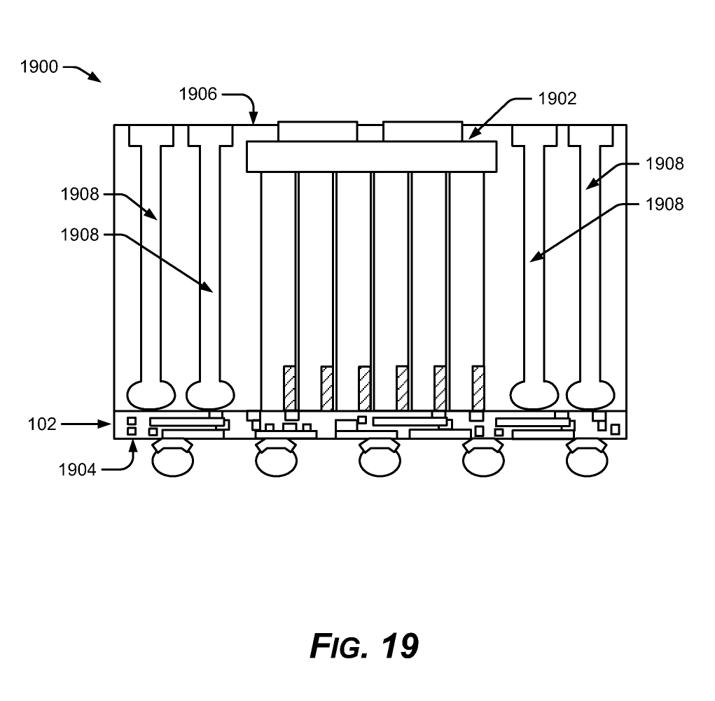

FIG. 19 shows another additional embodiment of the example vertical memory modules 1900 with fan-out redistribution layers (RDLs) 102 & 1902 on silicon sidewalls 104 or other sidewalls 104. This embodiment may have redistribution layers (RDLs) 102 & 1902 on both front sides 1904 and back sides 1906 of the package 1900. The package 1900 may additionally or alternatively have one or more interconnects 1908 extending through the package 1900. For example, wire bonds, Bond Via Array (BVA®) technology, copper pillars, or through-mold vias may be provided to transfer signals from the front side 1904 to the back side 1906, for example (Invensas Corporation, San Jose, Calif.). This example configuration enables stacking on the back side 1906, when desirable.

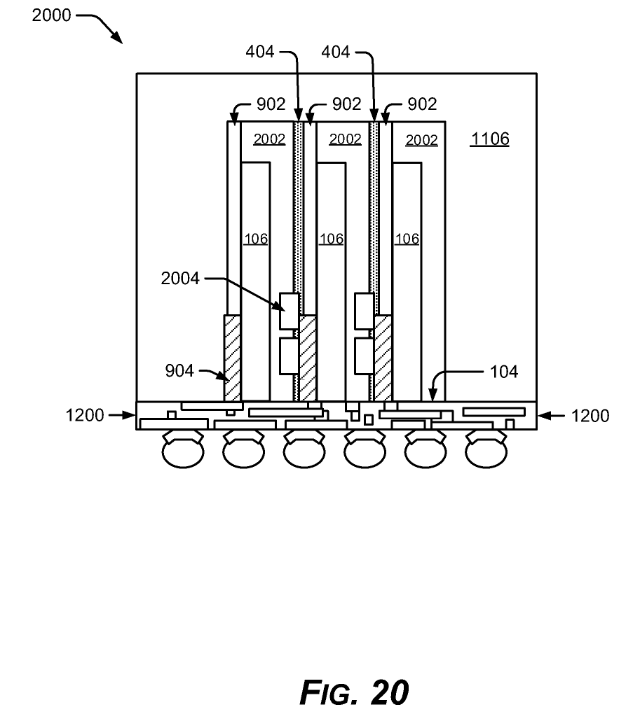

FIG. 20 shows another additional embodiment of the example vertical memory modules 2000 with fan-out redistribution layers (RDLs) 1200 on silicon sidewalls 104 or other sidewalls 104. This embodiment can be produced by the example alternative process of FIGS. 8-13. The alternative process can be used to place a thickness of molding material 2002 between the dies 106, with the die-face-side RDL 902 extended to the molding material 2002. Passive components 2004, such as capacitors, and even inductors, shields, heat or electrical dissipation elements, and even further, resistors, diodes, and simple transformers may be embedded or included in the molding material 118 or the adhesive layers 404.

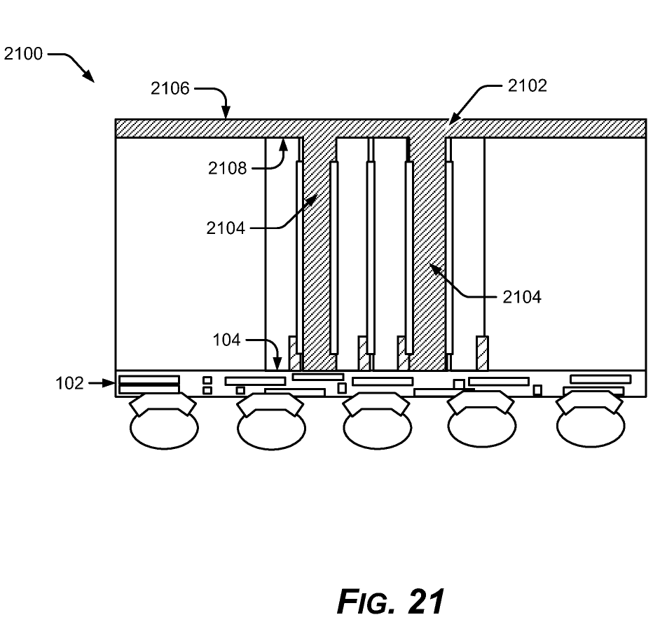

FIG. 21 shows another additional embodiment of the example vertical memory modules 2100 with fan-out redistribution layers (RDLs) 102 on silicon sidewalls 104 or other sidewalls 104. A heat conducting layer, heat pipe, and/or a heat spreading structure 2102 may be integrated into the stack or package design to dissipate excess heat. Heat sinking layers 2104 may be included in the initial stacking of dies 106 or chips, and then a heat spreader 2102 or heat dissipating layer in thermal communication with the heat sinking layers 2104 can be disposed as an outside surface 2106, placed on or near such the sidewall 2108 opposing the RDL sidewall 104, for example.

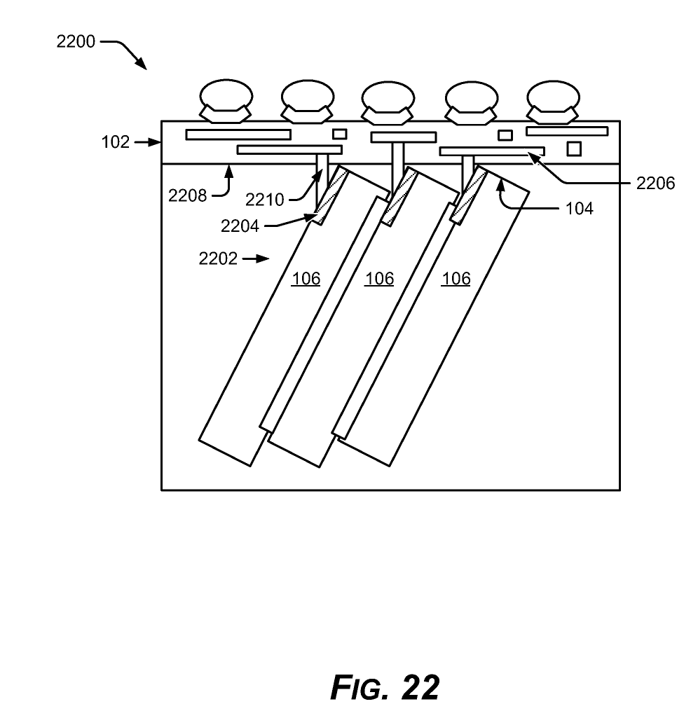

FIG. 22 shows another additional embodiment of the example vertical memory modules 2200 with fan-out redistribution layers (RDLs) 102 on silicon sidewalls 104 or other sidewalls 104. In this example embodiment, a tilted configuration 2202 of the stacked memory dies 106 can enable improved access to the memory chip signal pads 2204 during RDL patterning. The tilted orientation 2202 of the stack of dies 106 in relation to the RDL layer 102 on the sidewall 104 increases the accessible surface area of a target pad 2204 on a tilted die 106 for connecting a redistribution trace 2206 to the pad, from the point of view of a conductor on the RDL surface 2208. The RDL 102 may optionally be augmented with a bump, wire bond, or other suitable extension element 2210 to extend the electrical connections vertically, if desired.

Example Methods

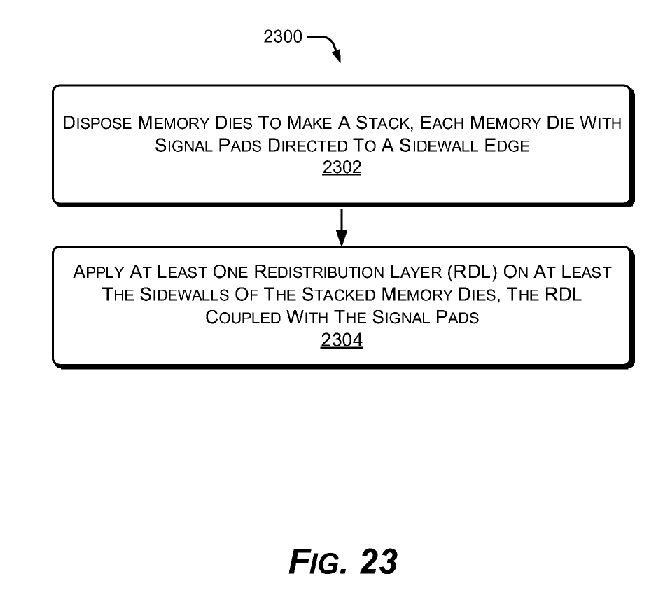

FIG. 23 shows an example method 2300 of making a memory module enabled by a fan-out redistribution layer (RDL). In the flow diagram, the operations are shown in individual blocks.

At block 2302, in an implementation, the method 2300 includes disposing memory dies to make a stack, each memory die having respective signal pads directed to an edge at or near a sidewall at one end of the memory die in a common direction with the signal pads of the other memory dies.

At block 2304, at least one redistribution layer (RDL) is applied on at least the sidewalls of the stacked memory dies, the at least one redistribution layer (RDL) communicatively coupled with the signal pads at the sidewalls of the memory dies.

The example method 2300 may include building the RDL on the sidewall to communicatively couple the RDL to the signal pads with solderless connections, or may include applying a solderless process to communicatively couple the RDL to the signal pads, without solder joints.

The example method 2300 may further comprise building the RDL as a fan-out of conductive lines from the signal pads, to under bump metallization (UBM) or to solder balls, for example.

The example method 2300 may further comprise building multiple redistribution layers (RDLs) on the sidewall, or on a combination of sides of the memory dies including a sidewall.

The example method may further comprise a die first process, a redistribution layer (RDL)-first process, or a fan-out RDL on individual memory chips-first process.

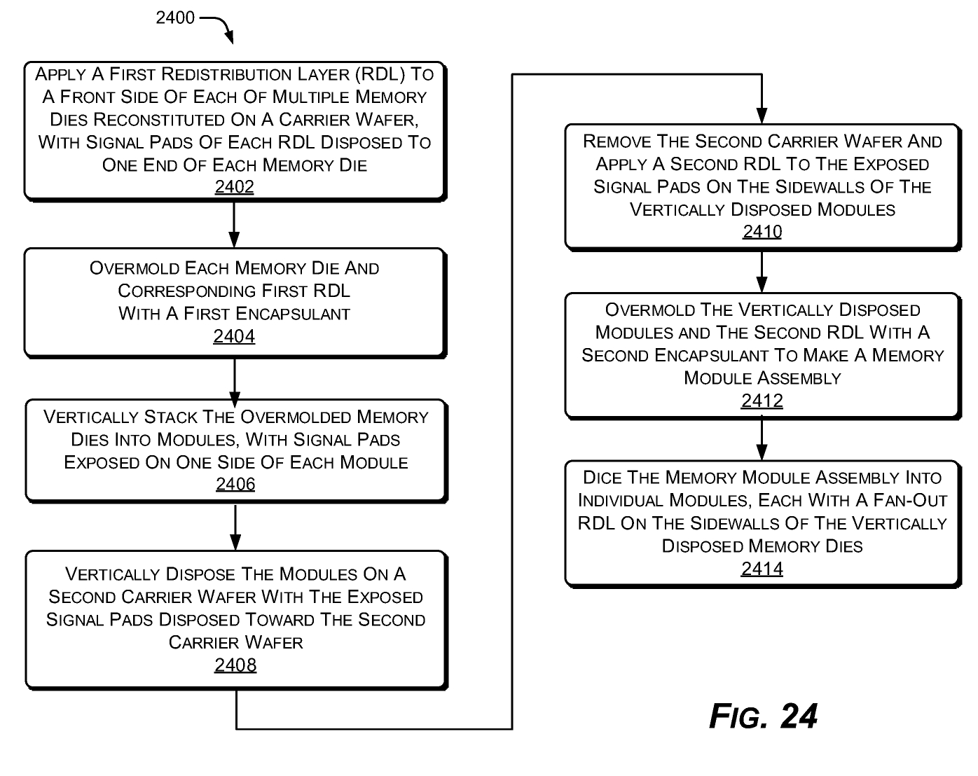

FIG. 24 shows an example method 2400 of making a memory module enabled by a fan-out redistribution layer (RDL). In the flow diagram, the operations are shown in individual blocks.

At block 2402, the example method 2400 includes applying a first redistribution layer (RDL) to a front side of each of multiple memory dies reconstituted on a carrier wafer, with signal pads of each RDL disposed to one end of each memory die.

At block 2404, each memory die and corresponding first RDL are overmolded with a first encapsulant.

At block 2406, the overmolded memory dies with first RDLs are vertically stacked into modules, with the signal pads exposed on one side of each module.

At block 2408, the modules are vertically disposed to be reconstituted on a second carrier with the exposed signal pads disposed toward the second carrier wafer.

At block 2410, the second carrier wafer is removed and a second RDL or RDLs are applied to the exposed signal pads on the sidewalls of the vertically disposed modules.

At block 2412, the vertically disposed modules and the second RDL(s) are overmolded with a second encapsulant to make a memory modules assembly. The same mold material may be used for the first and second encapsulants.

At block 2414, the memory modules assembly is singulated into individual memory modules, each with a fan-out redistribution layer on the sidewalls of the vertically disposed memory dies.

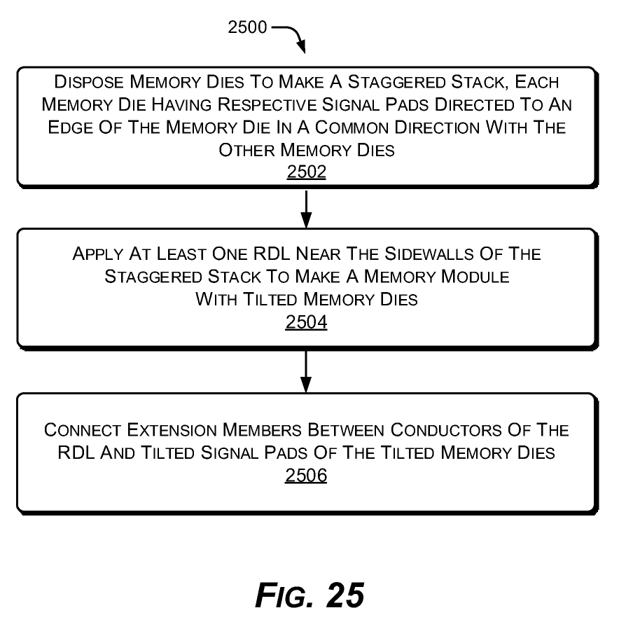

FIG. 25 shows an example method 2500 of making a memory module enabled by a fan-out redistribution layer (RDL). In the flow diagram, the operations are shown in individual blocks.

At block 2502, in an implementation, the method 2500 includes disposing memory dies to make a staggered stack, each memory die having respective signal pads directed to an edge at or near a sidewall at one end of the memory die in a common direction with the signal pads of the other memory dies.

At block 2504, at least one redistribution layer (RDL) is applied near the sidewalls of the staggered stack of memory dies to make a memory module with tilted memory dies.

At block 2506, conductive extension members are connected between conductors of the RDL and the tilted signal pads of the tilted memory dies, communicatively coupling the at least one redistribution layer (RDL) with the tilted signal pads at the sidewalls of the tilted memory dies. The tilted signal pads provide a larger target area for vertical connection between RDL conductors and the signal pads of the memory dies.

In the specification and appended claims: the terms “connect,” “connection,” “connected,” “in connection with,” and “connecting,” are used to mean “in direct connection with” or “in connection with via one or more elements.” The terms “couple,” “coupling,” “coupled,” “coupled together,” and “coupled with,” are used to mean “directly coupled together” or “coupled together via one or more elements.”

While the present disclosure has been disclosed with respect to a limited number of embodiments, those skilled in the art, having the benefit of this disclosure, will appreciate numerous modifications and variations possible given the description. It is intended that the appended claims cover such modifications and variations as fall within the true spirit and scope of the disclosure.

1. A method, comprising:
disposing multiple memory dies to make a vertical stack, each memory die having a respective signal pad directed to an edge of the memory die in a common direction with the signal pads of the multiple memory dies; and
building a redistribution layer (RDL) on a sidewall of the stack of memory dies, the redistribution layer (RDL) perpendicular to the vertical stack and communicatively coupled with the signal pads.

2. The method of claim 1, wherein building the RDL on the sidewall includes communicatively coupling the RDL to the signal pads with solderless connections, or includes applying a solderless process to communicatively couple the RDL to the signal pads.

3. The method of claim 1, further comprising building the RDL as a fan-out of conductive lines from the signal pads.

4. The method of claim 1, further comprising building the RDL to fan-out conductive lines from the signal pads to under ball metallization or to solder balls.

5. The method of claim 1, further comprising building multiple redistribution layers (RDLs) on the sidewall.

6. The method of claim 1, further comprising one of a die first process, a redistribution layer (RDL)-first process, or a fan-out RDL on individual memory chips-first process.

7. A memory module, comprising:
a package for memory with one or more redistribution layers (RDLs) built on a sidewall of a memory die, or on sidewalls of a stack of memory dies, or on sidewalls of a combination of memory dies and logic dies; and
wherein the memory dies or logic dies each have a respective signal pad routed to the sidewalls.

8. The memory module of claim 7, wherein the one or more redistribution layers (RDLs) are solderlessly connected to the signal pads of the memory dies.

9. The memory module of claim 7, wherein at least the memory dies are tilted away from perpendicular with respect to the one or more redistribution layers (RDLs) layers.

10. A memory package, comprising:
memory dies disposed vertically into a stack with sidewall sides of the memory dies aligned with each other;
signal pads of each memory die disposed at or near each respective sidewall side; and
one or more redistribution layers (RDLs) built and fanned-out on the aligned sidewall sides.

11. The memory package of claim 10, wherein at least one of the RDLs connects to the signal pads without solder joints and without a soldering process.

12. The memory package of claim 10, further comprising first RDLs with signal pads directed along a front side of each memory die perpendicular to the aligned sidewall sides;
wherein the memory dies and associated first RDLs are vertically stacked with signal pads of the first RDLs directed to the aligned sidewall sides; and
a second RDL applied on the aligned sidewall sides perpendicular to the first RDLs.

13. The memory package of claim 12, further comprising a first molding material encapsulating each memory die and respective first RDL; and
a second molding material encapsulating groups of the vertically stacked memory dies and respective first RDLs into individual memory modules.

14. The memory package of claim 10, further comprising a ZiBond low temperature bond between the memory dies in the stack.

15. The memory package of claim 10, further comprising a logic chip within the stack of memory dies, wherein the logic chip comprises one of a buffer, a controller, or an equalizer.

16. The memory package of claim 10, further comprising a logic chip connected on an opposing side of the RDL from the stacked memory dies.

17. The memory package of claim 10, further comprising a RDL on both front and back sides of the package; and
at least one conductive interconnect to transfer signals from a front side to a back side of the memory package.

18. The memory package of claim 10, further comprising a passive electronic component embedded in a molding material or in an adhesive layer of the memory package.

19. The memory package of claim 10, further comprising a heat sink, heat conducting layer, and/or a heat spreading structure associated with the stack of memory dies.

20. The memory package of claim 10, further comprising tilted memory dies, each memory die tilted with respect to the RDL; and
conductive extension elements to vertically connect signal pads of the RDL to respective tilted signal pads of the tilted memory dies.
